(19) United States
(12) Patent Application Publication
(10) Pub. No.: US 2025/0285841 A1
(43) Pub. Date: Sep. 11, 2025

(54) SYSTEMS, METHODS, AND APPARATUSES FOR ATMOSPHERIC PRESSURE PLASMA JET NOZZLES

(71) Applicant: CORNING PRECISION MATERIALS Co., LTD., ASAN-SI (KR)

(72) Inventor: Woo Jin Lee, Cheonan (KR)

(21) Appl. No.: 19/050,650

(22) Filed: Feb. 11, 2025

Related U.S. Application Data
(60) Provisional application No. 63/562,341, filed on Mar. 7, 2024.

(51) Int. Cl. H01J 37/32; C03C 23/00

(52) U.S. Cl. CPC H01J 37/32449; C03C 23/006; H01J 37/32568; H01J 37/32825; H01J 2237/336

(57) ABSTRACT

According to one or more other aspects of the present disclosure, a nozzle for an atmospheric pressure plasma jet (APPJ) includes a housing having an upstream end, a downstream end, and an inner wall defining a channel extending axially through the housing from the upstream end and the downstream end. The nozzle further includes a cathode disposed within the channel proximate to the upstream end of the housing. The downstream end of the housing includes a first end surface, the first end surface bisects at least a portion of the channel to form an opening through the first end surface, and a first point on the first end surface at the inner wall is disposed downstream of a second point on the first end surface so that a plasma generated by the nozzle preferentially flows off axis in a direction of the second point.

### CROSS-REFERENCE TO RELATED APPLICATIONS

This application claims the benefit of priority of U.S. Provisional Patent Application Ser. No. 63/562,341, filed on Mar. 7, 2024, the content of which is relied upon and incorporated herein by reference in its entirety.

### FIELD OF THE DISCLOSURE

The present specification generally relates to systems, methods, and apparatuses for atmospheric plasma jet nozzles and, more specifically, to systems, methods and apparatuses utilizing atmospheric pressure plasma jets to cure materials.

### BACKGROUND

Various technologies are currently being used and/or developed in order to cure materials. Specifically, atmospheric pressure plasma jets (APPJs) are currently employed for the treatment of glass materials. Systems utilizing APPJs include nozzles with openings that direct plasma toward a center of the nozzle. Such nozzles have an increased concentration of plasma in the center of the plasma stream and, thus, possess an increased temperature at the center of the plasma stream compared to that of the rest of the plasma stream. These inconsistent temperatures result in inconsistent curing of the glass materials. Moreover, plasma streams exiting nozzles of current APPJs are often characterized by turbulent flow, further exacerbating inconsistencies in the curing of glass materials. This often results in damage to the glass material, as some portions of the glass material may be over cured.

### SUMMARY

Accordingly, there is an ongoing need for systems, methods, and apparatuses for APPJ nozzles. A first aspect may include a nozzle for an atmospheric pressure plasma jet (APPJ). The nozzle may include a housing having an upstream end, a downstream end, and an inner wall defining a channel extending axially through the housing from the upstream end and the downstream end, and a cathode disposed within the channel proximate to the upstream end of the housing. The cathode and the housing may be coaxial and form an annular flow path. The inner wall may have a circular cross-sectional shape downstream of the cathode and the downstream end of the housing may include a first end surface. The first end surface may bisect at least a portion of the channel to form an opening through the first end surface and a first point on the first end surface at the inner wall may be disposed downstream of a second point on the first end surface so that a plasma generated by the nozzle may preferentially flow off axis in a direction of the second point.

A second aspect of the present disclosure may include the first aspect, wherein the first end surface may form an angle less than or equal to 50 degrees with a plane perpendicular to a center axis of the nozzle.

A third aspect of the present disclosure may include the second aspect, wherein the angle between the first end surface and the plane perpendicular to the center axis of the nozzle may be from 1 degrees to 50 degrees, or from 10 degrees to 50 degrees, or from 10 degrees to 40 degrees, or from 15 degrees to 30 degrees.

A fourth aspect of the present disclosure may include either one of the second or third aspects, which may further include a second end surface, wherein the second end surface may bisect another portion of the channel and is perpendicular to the center axis.

A fifth aspect of the present disclosure may include any one of the first through fourth aspects, wherein the first end surface may bisect the entire channel, and a shape of the opening in the first end surface in a plane of the first end surface may be elliptical.

A sixth aspect of the present disclosure may include any one of the first through fifth aspects, wherein the housing may be an anode for formation of the APPJ.

A seventh aspect of the present disclosure may include any one of the first through sixth aspects, wherein a primary flow vector of the plasma exiting the channel through the opening may be drawn toward the second point of the opening.

An eighth aspect of the present disclosure may include any one of the first through seventh aspects, wherein the upstream end of the housing may be rotatably coupled to an anode of the APPJ.

A ninth aspect of the present disclosure may include any one of the first through eighth aspects, herein the plasma may be diffused as it exits the opening of the nozzle.

A tenth aspect of the present disclosure may include any one of the first through ninth aspects, wherein at least a portion of the opening may be formed through cutting a portion of the nozzle.

An eleventh aspect of the present disclosure may include any one of the first through tenth aspects, wherein the nozzle may be cast out of a metal.

A twelfth aspect of the present disclosure may include a method of material processing. The method may include generating a plasma plume with an APPJ according to the nozzle of any one of the first through eleventh aspects. The plasma plume may have an average flow vector that diverges from a center axis of the nozzle. The method may also include rotating the nozzle, wherein the rotating may cause the plasma plume to follow a circular path circumscribing the center axis of the nozzle. The method may further include contacting the material with the plasma plume, wherein the average flow vector of the plasma plume may diverge from the center axis of the nozzle and rotation of the nozzle may provide consistent contact of the plasma plume with the material.

A thirteenth aspect of the present disclosure may include the twelfth aspect, which may further include linearly translating the APPJ relative to the material.

A fourteenth aspect of the present disclosure may include either one of the twelfth or thirteenth aspects, which may further include linearly translating the material relative to the APPJ.

A fifteenth aspect of the present disclosure may include any one of the twelfth through fourteenth aspects, wherein a maximum temperature of the plasma plume may be from 900° C. to 1,500° C., or from 1,000° C. to 1,500° C., or from 1,100° C. to 1,400° C., or from 1,200° C. to 1,400° C.

A sixteenth aspect of the present disclosure may include any one of the twelfth through fifteenth aspects, wherein a maximum temperature difference within the plasma plume may be less than or equal to 150° C.

A seventeenth aspect of the present disclosure may include any one of the twelfth through sixteenth aspects, wherein the material may be a glass edge.

An eighteenth aspect of the present disclosure may include the seventeenth aspect, wherein the glass edge may be cured to a roughness of less than 150 nanometers.

A nineteenth aspect of the present disclosure may include either one of the seventeenth or eighteenth aspects, wherein the circular path circumscribing the center axis of the nozzle may include an outer diameter of from 0.5 times to 2.5 times a glass edge width, or from 1.0 times to 2.5 times a glass edge width, or from 1.0 times to 2.0 times a glass edge width.

A twentieth aspect of the present disclosure may include any one of the twelfth through nineteenth aspects, wherein a distance from the opening of the nozzle and the material may be from 1.0 millimeters to 8.0 millimeters, or from 2.0 millimeters to 8.0 millimeters, or from 2.0 millimeters to 6.0 millimeters.

A twenty-first aspect of the present disclosure may include any one of the twelfth through twentieth aspects, wherein the nozzle may be rotated from 1,000 rotations per minute to 4,000 rotations per minute, or from 1,200 rotations per minute to 3,500 rotations per minute, or from 1,200 rotations per minute to 3,000 rotations per minute.

A twenty-second aspect of the present disclosure may include any one of the twelfth through twenty-first aspects, wherein a plasma flow out of the opening may be laminar flow.

Additional features and advantages of the technology disclosed herein will be set forth in the detailed description which follows, and in part will be readily apparent to those skilled in the art from that description or recognized by practicing the technology as described herein, including the detailed description which follows, the claims, as well as the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate the various embodiments described herein, and together with the description serve to explain the principles and operations of the claimed subject matter.

### BRIEF DESCRIPTION OF THE DRAWINGS

The following detailed description of specific embodiments of the present disclosure can be best understood when read in conjunction with the following drawings, in which like structure may be indicated with like reference numerals and in which:

FIG. 1 schematically depicts a cross-sectional view of a prior art nozzle for an atmospheric pressure plasma jet (APPJ);

FIG. 2 schematically depicts a cross-sectional view of the prior art nozzle of the APPJ of FIG. 1 curing a glass edge;

FIG. 3 schematically depicts a cross-sectional view of an APPJ with a nozzle having an elliptical surface, according to embodiments shown and described herein;

FIG. 4A schematically depicts a side-view of a portion of the nozzle of FIG. 3, according to embodiments shown and described herein;

FIG. 4B schematically depicts a front-view of a portion of the nozzle of FIG. 3, according to embodiments shown and described herein;

FIG. 5 schematically depicts a cross-sectional view of the nozzle of FIG. 3, according to embodiments shown and described herein;

FIG. 6 schematically depicts a view of the nozzle of FIG. 5 taken from the perspective of reference line 6-6 in FIG. 5, according to embodiments shown and described herein;

FIG. 7 schematically depicts an APPJ nozzle with a first portion of the end surface being perpendicular to a center axis of the APPJ nozzle and a second portion angled relative to the first portion, according to embodiments shown and described herein;

FIG. 8A schematically depicts a view of the nozzle of FIG. 7 taken from the perspective of reference line 8A-8A in FIG. 7, according to embodiments shown and described herein;

FIG. 8B schematically depicts a view of the nozzle of FIG. 7 taken from the perspective of reference line 8B-8B in FIG. 7, according to embodiments shown and described herein;

FIG. 9 schematically depicts a side-view of an APPJ with a nozzle with an elliptical surface curing a glass edge, according to embodiments shown and described herein;

FIG. 10A schematically depicts a perspective view of a prior art APPJ nozzle;

FIG. 10B schematically depicts end view of a plasma profile of the plasma plume produced by the prior art APPJ nozzle of FIG. 10A, according to embodiments shown and described herein;

FIG. 11A schematically depicts a perspective view of an APPJ nozzle with an angled end surface, according to embodiments shown and described herein;

FIG. 11B schematically depicts a plasma profile of the plasma plume produced by the APPJ nozzle of FIG. 11A, according to embodiments shown and described herein;

FIG. 12A schematically depicts a photograph of a glass edge cured by the prior art APPJ nozzle of FIG. 10A; and

FIG. 12B schematically depicts schematically depicts a photograph of a glass edge cured by the APPJ nozzle of FIG. 11A, according to embodiments shown and described herein.

### DETAILED DESCRIPTION

Embodiments of the present disclosure are described in the detailed description, which follows, examples of which are illustrated in the accompanying drawings. Whenever possible, the same reference numerals will be used throughout the drawings to refer to the same or like parts. The present disclosure may be directed to systems, methods, and apparatuses for an atmospheric pressure plasma jet (APPJ) nozzle. Specifically, the systems, methods, and apparatuses disclosed herein may be directed to an APPJ nozzle that directs and diffuses the plasma plume produced therein while rotating in order to evenly cure a glass edge. Referring now to FIG. 3, an APPJ nozzle 100 is depicted. The nozzle 100 may include a housing 102 having an upstream end 102A and a downstream end 102B. The housing 102 may also include an inner wall 104 defining a channel 106 extending axially through the housing 102 from the upstream end 102A and the downstream end 102B. The APPJ may include a cathode 108 disposed within the channel 106 proximate to the upstream end 102A of the housing 102. The cathode 108 and the housing 102 may be coaxial and may form an annular flow path. The inner wall 104 may have a circular cross-sectional shape downstream of the cathode 108. The downstream end 102B of the housing 102 may include a first end surface 112, which may bisect at least a portion of the channel 106 to form an opening 114 through the first end surface 112. A first point 116 on the first end surface 112 at the inner wall 104 may be disposed downstream of a second point 118 on the first end surface 112 so that plasma generated by the nozzle 102 may preferentially flow off axis in a direction of the second point 118.

Unless otherwise expressly stated, it is in no way intended that any method set forth herein be construed as requiring that its steps be performed in a specific order, nor that specific orientations be required with any apparatus. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

Where a range of numerical values is recited herein, comprising upper and lower values, unless otherwise stated in specific circumstances, the range is intended to include the endpoints thereof, and all integers and fractions within the range. It is not intended that the scope of the disclosure be limited to the specific values recited when defining a range. Further, when an amount, concentration, or other value or parameter is given as a range, one or more preferred ranges or a list of upper preferable values and lower preferable values, this is to be understood as specifically disclosing all ranges formed from any pair of any upper range limit or preferred value and any lower range limit or preferred value, regardless of whether such pairs are separately disclosed.

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such. For purposes of the present disclosure, the term “about” when used in reference to a numerical value means the numerical value is within a range defined by ±5% of the numerical value.

Directional terms as used herein-for example up, down, right, left, front, back, top, bottom—are made only with reference to the figures as drawn and the coordinate axis provided therewith and are not intended to imply absolute orientation.

As used herein, the singular forms “a,” “an” and “the” include plural referents unless the context clearly dictates otherwise. Thus, for example, reference to “a” component includes aspects having two or more such components, unless the context clearly indicates otherwise.

As used throughout the present disclosure, the terms “upstream” and “downstream” refer to the relative positioning of features of a nozzle with respect to the direction of flow of materials through the nozzle. A first feature of the nozzle may be considered “upstream” of a second feature of the nozzle if materials flowing through the nozzle encounter the first feature before encountering the second feature. Likewise, the second feature may be considered “downstream” of the first feature if materials flowing through the nozzle encounter the first feature before encountering the second feature.

As used throughout the present disclosure, the term “plasma” refers to an ionized gas comprising positive ions and free electrons.

As used throughout the present disclosure, the term “atmospheric pressure plasma jet” refers to a flow of plasma discharged from an opening, wherein the plasma pressure approximately matches that of the surrounding atmosphere, including conditions wherein the plasma pressure is between 90% and 110% of 101.325 kilopascals (standard atmospheric pressure).

As used throughout the present disclosure, the term “particle” refers to any type of solid that can be present on a surface, such as but not limited to glass particles, dust particles, or other types of solids.

APPJs may be used for processing or cleaning materials. Plasma produced through APPJs may be categorized as dark discharge, glow discharge, and arc discharge. Specifically, arc discharge may be used to finish glass, such as glass edges. An APPJ includes a cathode, anode, and a passage for the plasma to pass there through. APPJs often include concentric nozzles that direct the plasma jet to a center of the nozzle.

As the plasma jet leaves the passage of the nozzle, the plasma jet mixes with ambient air. The plasma jet is diffused as it mixes with ambient air, resulting in inconsistent temperatures throughout the plasma jet, where a center of the plasma jet is a peak region with the highest temperature within the plasma jet. Treating glass with ordinary APPJ nozzles results in inconsistent treatment of glass, producing undesired abnormalities on the glass surface. When treating a glass edge, the plasma jet may be entrained on one side of the glass, causing turbulent flow. This results in further inconsistencies and undesired abnormalities, such as gaseous bubbles at or below the glass surface.

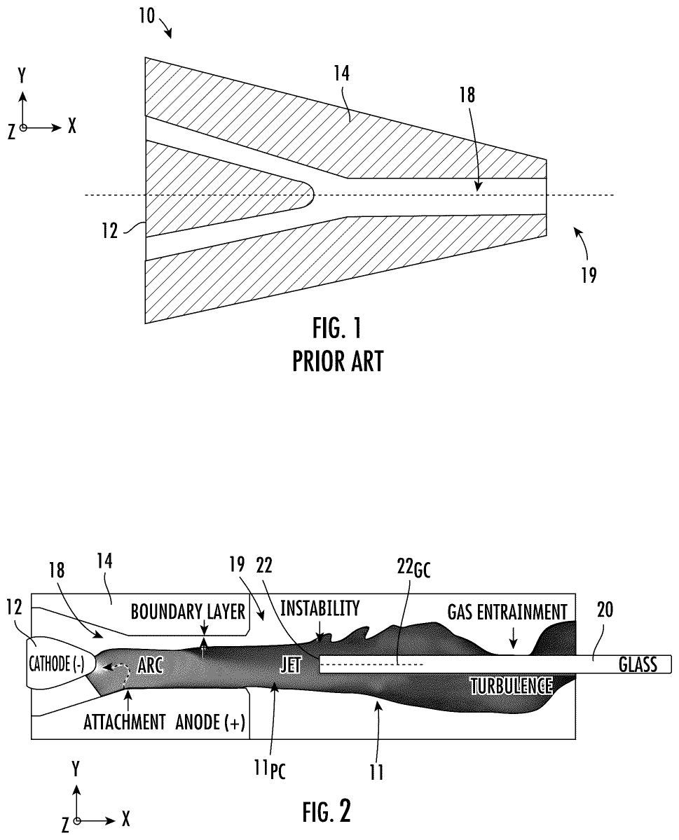

Referring now to FIG. 1, a conventional APPJ nozzle 10 for generating a plasma plume 11 (depicted in FIG. 2) according to the prior art is depicted. The conventional APPJ system 10 includes a cathode 12 and an anode 14. Ordinarily, APPJ nozzles 10 are concentric, as depicted in FIG. 1. The nozzle 10 directs a plasma plume 11 produced by the cathode 12 and anode 14 through a passage 18 of the nozzle and through an opening 19 of the nozzle 10, as discussed further below.

Referring now to FIG. 2, operation of the conventional APPJ nozzle 10 is depicted. Specifically, the APPJ nozzle 10 is depicted as treating a glass edge 22 of a glass substrate 20. The APPJ nozzle is used to produce the plasma plume 11 that travels through the passage 18 formed by the anode 14. An oxidation reaction occurs on the anode 14, while a reduction reaction occurs at the cathode 12. As the plasma plume 11 exits the nozzle 10, it begins to mix with ambient air. As such, a plasma plume center 11_{PC} of the plasma plume 11 (as depicted in FIG. 1) has a much higher density of plasma and, thus, has a much higher temperature than compared to portions of the plasma plume 11 off of the plasma plume center 11_{PC}. Moreover, as depicted in FIG. 2, the exiting of the plasma plume 11 from the concentric nozzle 10 results in turbulent flow due to gas entrainment on one side of the glass substrate 20. As such, the plasma plume 11 may oscillate up and down along the glass edge 22 (i.e., along the y-axis of FIG. 2).

When treating the glass edge, the APPJ nozzle 10 may be linearly translated along the glass edge 22 of the glass substrate 20 (i.e., in a direction of the Z-axis depicted in FIG. 2) to cure the glass edge 22. In embodiments, the APPJ nozzle 10 may be stationary and the glass substrate 20 moved linearly relative to the APPJ nozzle 10. However, the inconsistent densities of plasma leading to varying temperatures and the turbulent flow leading to oscillation of the plasma plume 11 lead to inconsistencies in treatment of the glass edge 22 of the glass substrate 20. Specifically, a glass edge center 22_{GC} of the glass edge 22 may be over treated/over cured, while a portion away from the glass edge center 22_{GC} of the glass edge 22 of the glass substrate may be under treated/under cured (as depicted in FIG. 12A, discussed further herein). Translating the APPJ nozzle 10 along the Z-axis at different rates and taking multiple passes over the glass edge 22 of the glass substrate 20 may reduce over treatment of the glass substrate 20. However, the inconsistencies in treatment of the glass edge 22 will still remain, as the plasma plume 11 would still have inconsistent plasma densities and turbulent flow.

The present disclosure solves these problems by providing systems, methods, and apparatuses for an APPJ nozzle that preferentially flows the plasma generated by the nozzle off axis and rotates the APPJ nozzle to diffuse the plasma and generate a plasma plume with consistent plasma densities and, thus, low temperature differences. The rotation of the APPJ nozzle as it linearly translates along the glass edge of the glass substrate yields a more consistent treatment of the glass edge, eliminating over/under treatment of either the glass edge center or glass edge outer portion. Referring again to FIG. 3, the APPJ nozzle 100 is depicted. The nozzle 100 comprises a housing 102 having an upstream end 102A and a downstream end 102B. The housing 102 also comprises the inner wall 104 defining the channel 106 extending axially through the housing 102 from the upstream end 102A to the downstream end 102B. The cathode 108 is disposed within the channel 106 proximate to the upstream end 102A of the housing 102. The cathode 108 and the housing 102 are coaxial and form an annular flow path. The inner wall 104 has a circular cross-sectional shape downstream of the cathode 108.

The downstream end 102B of the housing 102 comprises the first end surface 112 and the first end surface 112 may bisects at least a portion of the channel 106 to form the opening 114 through the first end surface 112. The first point 116 on the first end surface 112 at the inner wall 104 is disposed downstream of the second point 118 on the first end surface 112 so that the plasma generated by the nozzle 100 preferentially flows off axis in a direction of the second point 118.

The nozzle 100 may include the cathode 108 disposed within the channel 106. The cathode 108 may undergo a reduction reaction (i.e., a decrease in oxidation state) through a transfer of electrons with the anode 120. The cathode 108 may include manganese silver, lithium cobalt oxide, lithium manganese oxide, lithium nickel manganese cobalt oxide, or combinations thereof. The anode 120 may include tungsten-based metals. Other materials for the cathode 108 and the anode 120 are contemplated. The cathode 108 and the anode 120 may be separated by a gap of from 0.1 mm to 1.0 mm, from 0.2 mm to 1.0 mm, from 0.3 mm to 1.0 mm, from 0.2 mm to 0.9 mm, from 0.2 mm to 0.8 mm, from 0.2 mm to 0.6 mm, from 0.2 mm to 0.4 mm, or any other distance suitable for a transfer of electrons from the anode 120 to the cathode 108.

Referring again to FIG. 3, in embodiments, a gas 122 may be run through one or more gas inlets 124 at the upstream end 102A of the housing 102, around the cathode 108 before entering the channel 106. The gas 122 may be forced through the gas inlet 124 through the use of one or more pumps 126. There may also be a gas control valve 128 at the gas inlet 124. The gas control valve 128 may allow the gas 122 to enter the gas inlet 124 when the gas control valve 128 is in an open position. Alternatively, when the gas control valve 128 is in a closed position, the gas 122 may be prevented from entering the gas inlet 124. The gas control valve 128 may include a ball valve, plug valve, check valve, or any other suitable valve for allowing/preventing the gas 122 from entering the gas inlet 124.

The gas 122 may be any gas that can be exited and at least partially converted to a plasma state in the nozzle 100. The gas 122 may include at least one component selected from the group consisting of nitrogen, argon, oxygen, hydrogen, helium, and combinations thereof. In embodiments, the gas 122 comprises at least one component selected from the group consisting of nitrogen, argon, and hydrogen. For example, the gas 122 may include at least two components selected from the group consisting of nitrogen, argon, and hydrogen, or the gas 122 can include each of nitrogen, argon, and hydrogen. When the gas 122 comprises at least one of nitrogen, argon, and hydrogen, the nitrogen content can, for example, range from about 50 mol % to about 100 mol %, such as from about 60 mol % to about 90 mol %. The argon content can, for example, range from about 0 mol % to about 20 mol %, such as from about 5 mol % to about 15 mol %. The hydrogen content can, for example, range from about 0 mol % to about 10 mol %, such as from about 1 mol % to about 5 mol %.

The gas inlet 124 may be in fluid communication with a gas source 125. The gas source 125 may store the gas 122 prior to the gas 122 entering the gas inlet 124. The gas source 125 may be a tank, vessel, or any other suitable container to store the gas 122. The gas 122 may also be pulled directly from ambient air, such that the gas source 125 is the ambient air.

In embodiments, the anode 102 may be the housing 102, such that the anode 120 include the features of the housing (e.g., the channel 106, the first end surface 112, and the gas inlet 124). In other embodiments, the upstream end 102A of the housing 102 may be rotatably coupled to the anode 120 of the APPJ. As such, the housing 102 may include housing threading 103 that threadingly engages anode threading 121 of the anode 120. The housing 102 and the anode 120 may be made of the same or different materials.

Referring still to FIG. 3, the housing 102 may include the inner wall 104 which may define the channel 106 extending axially through the housing 102 from the upstream end 102A to the downstream end 102B of the housing 102. The inner wall 104 may be circular in cross-section, as depicted in FIG. 3, to define the channel 106 as circular cylindrical channel. In embodiments, the inner wall 104 may also be elliptical in cross-section, oval in cross-section, or any other suitable shape. The inner wall 104 may be uniform in cross-section downstream of the cathode 108. Alternatively, downstream of the cathode 108, the inner wall 104 may be conical in shape, such that the diameter of the inner wall 104 decreases from the cathode 108 to the downstream end 102B of the housing 102. The channel 106 defined by the inner wall 104 may have a diameter of from 2 mm to 8 mm, such as from 3 mm to 8 mm, from 4 mm to 8 mm, from 2 mm to 6 mm, or from 2 mm to 4 mm. In embodiments, the diameter of the channel 106 defined by the inner wall 104 may be relative to dimensions of a glass edge 202 of a glass substrate (described further herein below).

The downstream end 102B of the housing 102 may include the first end surface 112. The first end surface 112 may bisect at least a portion or all of the channel 106. As such, the first end surface 112 and the inner wall 104 may define at least a portion of or all of the opening 114 through the first end surface 112. In embodiments, the first end surface 112 may include the first point 116 that is disposed downstream of the second point 118 on the first end surface 112. The first end surface 112 being shaped in such a way that causes the plasma generated by the nozzle 100 to preferentially flow in an off-axis direction (i.e., in a direction not parallel to the center axis 101 of the nozzle 100) towards the second point 118, as depicted by a primary flow vector 111_{P} of the plasma drawn toward the second point 118 of the opening 114. The primary flow vector 111_{P} of the plasma is merely illustrative of a direction of the plasma flowing off of the center axis 101 toward the second point 118; the plasma may flow off the center axis 101 at any non-zero angle with respect to the center axis 101 and toward the second point 118 of the first end surface 112.

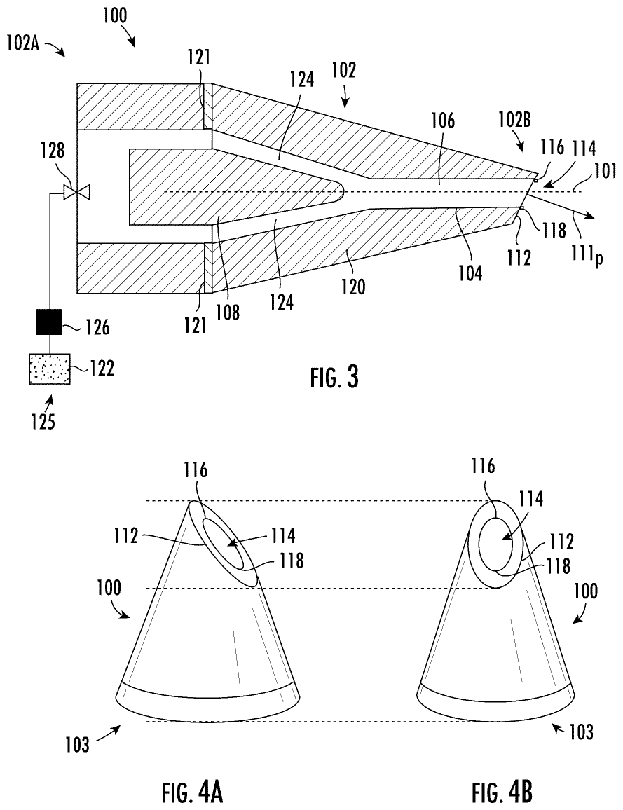

Referring now to FIGS. 4A and 4B, a side views of the nozzle 100 are depicted. In embodiments, the first end surface 112 may bisect the entire channel 106, such that a shape of the opening 114 formed by the first end surface 112 in a plane of the first end surface 112 is elliptical.

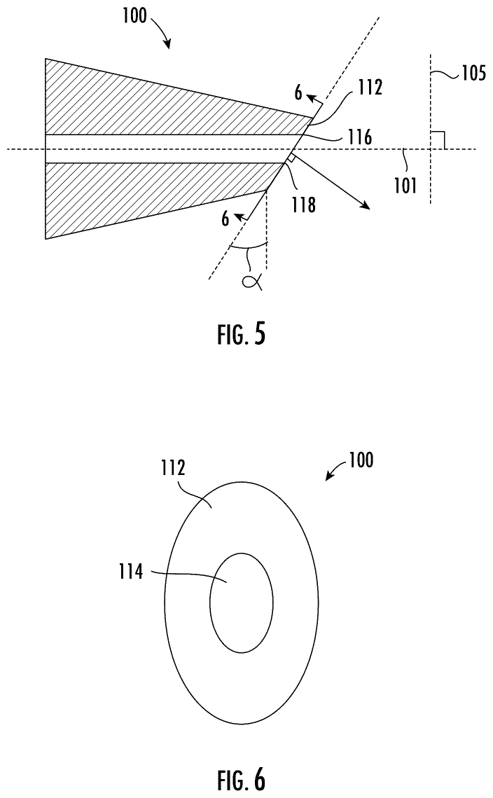

Referring now to FIG. 5, in embodiments, the first end surface 112 may form an angle α with a plane perpendicular 105 to the center axis 101 of the nozzle 100. The angle α may be greater than 0 (zero) and less than or equal to 50 degrees with the plane perpendicular 105 to the center axis 101 of the nozzle. In embodiments, the angle α between the first end surface 112 and the plane perpendicular 105 to the center axis 101 may be from 1 degrees to 60 degrees, such as from 1 degrees to 50 degrees, from 10 degrees to 60 degrees, from 10 degrees to 50 degrees, from 20 degrees to 50 degrees, from 10 degrees to 40 degrees, from 20 degrees to 40 degrees, or from 15 degrees to 30 degrees.

Increasing the angle α between the first end surface 112 and the plane perpendicular 105 to the center axis 101 may increase a degree to which the flow of plasma is off-axis in the direction of the second point 118, and, thus, the primary flow vector 111_{P} going off of the center axis 101 by a greater magnitude. Decreasing the angle α between the first end surface 112 and the plane perpendicular 105 to the center axis 101 may reduce the degree to which the flow of plasma is directed off-axis toward the second point 118. As such, the preferential flow of plasma toward the second point 118 can be adjusted based on the angle α between the first end surface 112 and the plane perpendicular 105 to the center axis 101. In embodiments, the angle that the primary flow vector 111_{P} forms with the center axis 101 may generally correspond to the angle α between the first end surface 112 and the plane perpendicular 105 to the center axis 101, such that the primary flow vector 111_{P} is normal to the plane of the first end surface 112.

Referring now to FIG. 6, the first end surface 112 may bisect the entire channel 106, such that the shape of the opening 114 in the first end surface 112 in a plane of the first end surface 112 is elliptical, as depicted in FIG. 6.

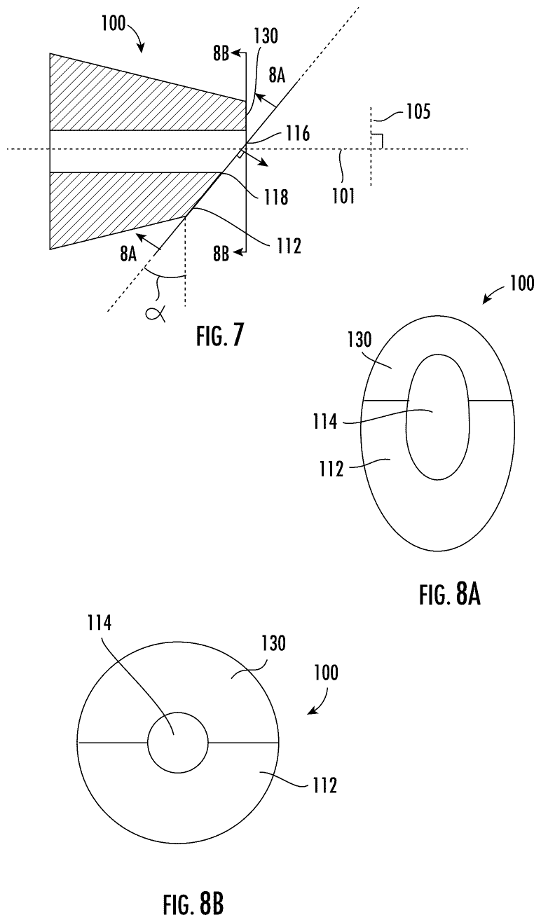

Referring now to FIG. 7, the first end surface 112 may bisect only a portion of the channel 106, and a second end surface 130 may bisect the remaining portion of the channel 106. The second surface 130 may be non-planar with the first end surface 112. In embodiments, the second surface 130 may be perpendicular to the center axis 101. In such embodiments, only the portion of the opening 114 defined by the first end surface 112 and the inner wall 104 in the plane of the first end surface 112 is elliptical in shape. The portion of the opening 114 defined by the inner wall 104 and the second end surface 130 is circular in the plane of the second end surface 130, as depicted in FIG. 8A.

In embodiments, the first end surface 112 may and the inner wall 104 may define 50% of the opening 114 while the second end surface 130 and the inner wall 104 may define the remaining portion of the opening 114. The first end surface 112 and the inner wall 104 may define 10%, 20%, 30%, 40%, 50%, 60%, 70%, 80%, 90%, or any other percentage of the opening 114, while the second end surface 130 and the inner wall 104 may define the remaining portion of the opening 114. Referring to FIG. 8B, the opening 114 is viewed in an end view in a direction parallel to the center axis of the nozzle 100. When viewed in a direction parallel to the center axis of the nozzle 100, the shape of the opening 114 may appear circular.

In embodiments, the first end surface 112 defining at least a portion of or all of the opening 114 may be formed by cutting a portion of the downstream end of the nozzle 100 along a plane forming an angle less than 90 degrees with the center axis of the nozzle 100. For example, the nozzle 100 depicted in FIG. 3 may be formed by cutting a distal portion at the downstream end of the nozzle 10 in FIG. 1, to form the first end surface 112 that bisects the channel 106 to form the first point 116 that is disposed downstream of the second point 118 as depicted in FIG. 3. The nozzle 100 may also be cast out of a metal. As such, there may be no need to cut the distal portion of the nozzle 10, as the first end surface 112 with the first point 116 disposed downstream of the second point 118 would result from the casting. The nozzle may be made of a metal with a high heat resistance, such as titanium, tungsten, stainless steel, nickel, or any other suitable metal. The nozzle 100 may also be made of the anode material, as noted hereinabove.

As noted hereinabove, the plasma exiting the channel 106 through the opening 114 may be directed off-axis toward the second point 118, such that the primary flow vector 111_{P} of the plasma is drawn toward the second point 118 of the opening 114 due to a rotation of the nozzle 100 (as described further below in the description of FIG. 9). The nozzle 100 may be rotated through the use of a stepping motor, a servo motor, or any other suitable device. The nozzle 100 may be rotated at a speed of from 500 rotations per minute to 4,000 rotations per minute, or from 1,000 rotations per minute to 4,000 rotations per minute, or from 1,000 rotations per minute to 3,500 rotations per minute, or from 1,200 rotations per minute to 3,500 rotations per minute, or from 1,200 rotations per minute to 3,000 rotations per minute, or from 1,500 rotations per minute to 3,000 rotations per minute, or from 1,500 rotations per minute to 2,000 rotations per minute.

Due to the off-axis flow vector of the plasma exiting the opening 114 and rotation of the nozzle 100, the plasma may be diffused to produce a more uniform/consistent plasma distribution when compared to that of the concentric nozzle 10 as described above. As a result, the maximum temperature within the plasma plume 140 may be decreased with respect to that of the maximum temperature within the plasma plume 11 generated by the prior art nozzle 10 described above in FIG. 1. The maximum temperature of the plasma plume 140 may be from 900° C. to 1,500° C., or from 900° C. to 1,400° C., or from 1,000° C. to 1,500° C., or from 1,000° C. to 1,400° C., or from 1,100° C. to 1,500° C., or from 1,100° C. to 1,400° C., or from 1,200° C. to 1,500° C., or from 1,200° C. to 1,400° C., or from 1,100° C. to 1,300° C., or from 1,250° C. to 1,350° C.

The plasma plume 140 may have a smaller maximum temperature difference within the plasma plume 140, as there is no concentration of plasma and heat at the center of the plasma plume 140 as there was in the plasma plume center 11_{PC} of the plasma plume 11 of the prior art nozzle 10. The maximum temperature difference within the plasma plume 140 may be less than or equal to 300° C., less than or equal to 250° C., less than or equal to 200° C., less than or equal to 150° C., less than or equal to 125° C., less than or equal to 100° C., or less than or equal to 75° C.

Referring now to FIG. 9, embodiments of the present disclosure may also include methods of processing a material 201, such as processing of the glass edge 202 of the glass substrate 200. The methods may include generating the plasma plume 140 with the APPJ having the nozzle 100 as described herein. The plasma plume 140 may have the average flow vector 111_{P} that diverges from the center axis 101 of the nozzle 100. As depicted in FIG. 9, the method may also include rotating the nozzle 100; rotating the nozzle 100 may cause the plasma plume 140 to follow a circular path circumscribing the center axis 101 of the nozzle 100. The methods may further include contacting the material 201 with the plasma plume 140. The average flow vector 111_{P} of the plasma plume 140 may diverge from the center axis 101 of the nozzle 100 and rotation of the nozzle 100 may provide consistent contact of the plasma plume 140 with the material 201. As noted hereinabove, the plasma plume 140 flowing out of the nozzle 100 may be laminar flow, which may result in more uniform processing of the material when compared to that of turbulent flow.

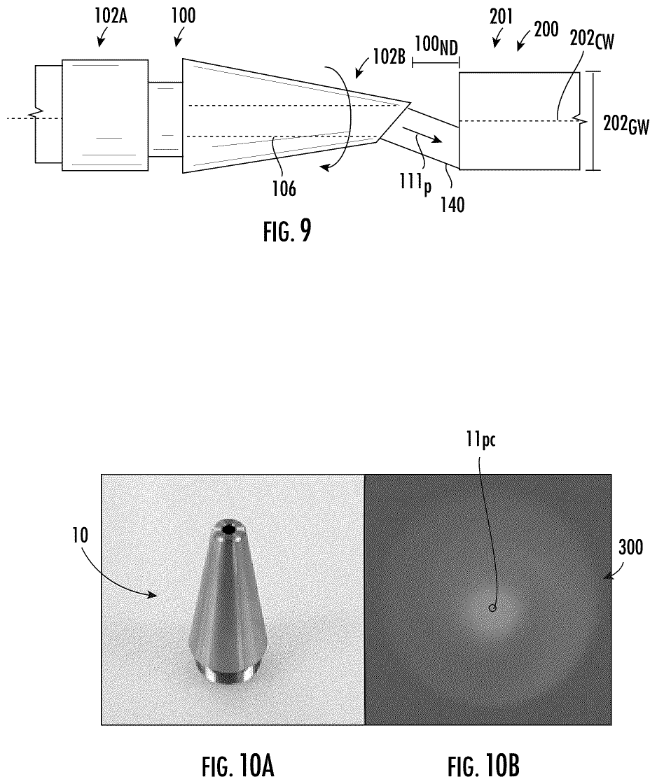

Referring now to FIG. 10A, the prior art nozzle 10 is depicted. The plasma plume 11 produced with the prior art nozzle 10 has a high concentration of plasma at the plasma plume center 11_{PC}. This is depicted in a first plasma profile 300 depicted in FIG. 10B generated by the prior art nozzle 10; a higher concentration of plasma is depicted at the center of the first plasma profile 300 and, thus, a higher temperature at the center of the plasma profile. This results in inconsistent treatment of material with the prior art nozzle 10.

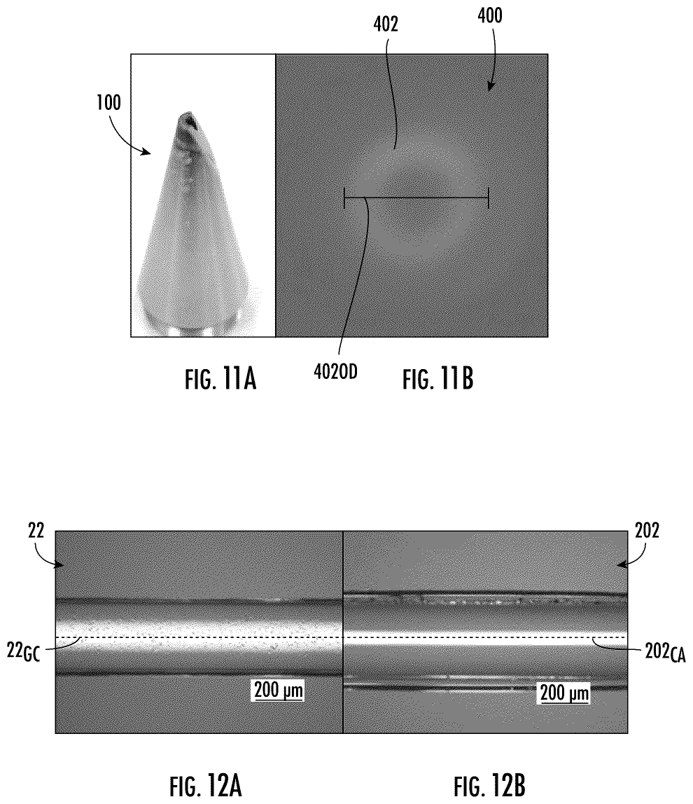

The nozzle 100 of the present disclosure is depicted in FIG. 11. As noted hereinabove, the nozzle 100 of the present disclosure produces a diffused plasma plume 140 with a low maximum temperature difference, which may include the average flow vector 111_{P} that diverges from the center axis 101 of the nozzle 100. When the nozzle 100 is rotated (as depicted in FIG. 9), the nozzle 100 produces a second plasma profile 400 depicted in FIG. 11B. The second plasma profile 400 does not include a high concentration of plasma at a center of the second plasma profile 400. Moreover, the circular path 402 in the plasma profile 400 produced by rotation of the nozzle 100 is not highly concentrated around the circular path 402. This is due to the low maximum temperature and low maximum temperature difference within the plasma plume 140 produced by the nozzle 100. The diffusion of plasma that results in the low maximum temperature difference within the plasma plume 140 also results in improved materials processing, as described further below.

Referring again to FIG. 9, the methods disclosed herein for processing a material may also include linearly translating the nozzle 100 relative to the material 201 (i.e., translating the nozzle 100 along the Z-axis depicted in FIG. 9). As such, the nozzle 100 may be simultaneously rotating and linearly translating, such as to contact each portion of the glass edge 202 of the glass substrate 200. In embodiments, the material 201 may be translated relative to the nozzle 100, such that the nozzle remains linearly stationary, but continues to rotate. In embodiments, each of the nozzle 100 and the glass edge 202 of the glass substrate 200 may linearly translated in opposite directions. The nozzle 100 may linearly translate relative to the glass edge 202, or the glass edge 202 may linearly translate relative to the nozzle 100, at a speed of from about 1 mm/s to about 50 mm/s. For example, the linear translation speed can be from about 1 mm/s to about 50 mm/s, from about 1 mm/s to about 25 mm/s, from about 1 mm/s to 20 mm/s, from about 5 mm/s to about 50 mm/s, from about 5 mm/s to about 25 mm/s, from about 5 mm/s to 20 mm/s, from about 10 mm/s to about 50 mm/s, from about 10 mm/s to about 25 mm/s, from about 10 mm/s to 20 mm/s, or any and all sub-ranges formed from any of these endpoints.

The methods disclosed herein may comprise rotating the nozzle 100 a speed of from 500 rotations per minute to 4,000 rotations per minute, or from 1,000 rotations per minute to 4,000 rotations per minute, or from 1,000 rotations per minute to 3,500 rotations per minute, or from 1,200 rotations per minute to 3,500 rotations per minute, or from 1,200 rotations per minute to 3,000 rotations per minute, or from 1,500 rotations per minute to 3,000 rotations per minute, or from 1,500 rotations per minute to 2,000 rotations per minute.

Referring again to FIG. 9, the APPJ nozzle 100 may rotate along the center axis 101 of the nozzle 100. As such, the plasma plume 140 may contact a different portion of the material 201 (i.e., the glass edge 202 of the glass substrate 200) at different points upon rotation. However, with the combination of linear and rotational movement, the plasma plume 140 generated by the nozzle 100 may contact each portion of the glass edge 202 of the glass substrate 200.

Referring now to FIG. 11B, the circular path 402 generated by the nozzle 100 may have an outer diameter 402_{OD} that depends on a glass edge width 202_{GW}. In embodiments, the outer diameter 402_{OD} of the circular path 402 generated by the nozzle 100 may equal the glass edge width 202_{GW} of the glass edge 202, such that the center axis 101 of the nozzle 100 is placed parallel to a center axis 202_{CA} of the glass edge 202 and the plasma plume 140 treats the entire glass edge width 202_{GW} when rotating and linearly translating along the glass edge 202. In embodiments, the circular path 402 generated by circumscribing the center axis 101 of the nozzle 100 includes an outer diameter of from 0.5 times to 3.0 times the glass edge width 202_{GW}, from 0.5 times to 2.5 times the glass edge width 202_{GW}, or from 1.0 times to 3.0 times the glass edge width 202_{GW}, or from 1.0 times to 2.5 times the glass edge width 202_{GW}, or from 1.0 times to 2.0 times the glass edge width 202_{GW}, or from 1.5 times to 2.5 times the glass edge width 202_{GW}.

Depending on the size of the circular path 402 relative to the glass edge width 202_{GW}, a distance 100_{ND} from the opening 114 of the nozzle 100 to the material 201 (e.g., the glass edge 202) may be adjusted. In embodiments, the distance 100_{ND} may be from 0.5 millimeters to 10.0 millimeters, or from 1.0 millimeters to 9.0 millimeters, or from 1.0 millimeters to 8.0 millimeters, or from 2.0 millimeters to 8.0 millimeters, or from 2.0 millimeters to 6.0 millimeters, or from 4.0 millimeters to 8.0 millimeters, or from 2.5 millimeters to 5.5 millimeters.

Referring now to FIG. 12A, a photo of the glass edge 22 treated with the prior art nozzle 10 is depicted. The glass edge 22 treated with the prior art nozzle 10 includes gas bubbles at or near the glass edge center 22_{GC} due to a higher temperature at the plasma plume center 11_{PC}, as discussed hereinabove. In contrast, a photo of the glass edge 202 treated with the nozzle 100 of the present disclosure is depicted in FIG. 12B. As depicted in FIG. 12B, the glass edge 202 treated with the nozzle 100 of the present disclosure does not include the gas bubbles or surface defects that are depicted in the glass edge center 22_{GC} of FIG. 12A. Utilization of the nozzle 100 and the methods described herein may result in a smooth glass edge 202 with little to no defects due to the consistent temperatures within the plasma plume 140, as discussed hereinabove. It is noted that the white line through the glass edge center 22_{GC} and through the glass edge center axis 202_{CA} of the glass edge 202 in FIGS. 12A and 12B, respectively, are due to a reflection of light on the photos of FIGS. 12A and 12B.

In embodiments, the methods disclosed herein for processing a material may cure the glass edge 202 (or any other desired material) to a desired roughness. The glass edge 202 may be cured to a roughness of less than 400 nanometers, less than 350 nanometers, less than 300 nanometers, less than 250 nanometers, less than 200 nanometers, less than 175 nanometers, less than 150 nanometers, less than 150 nanometers, less than 125 nanometers, or less than 100 nanometers. The roughness of the glass edge 202 when cured by the APPJ nozzle 100 may depend on the amount of passes the nozzle 100 takes over the glass edge 202.

The number of times that the nozzle 100 moves relative to an entire length of the material 201 in a single direction (i.e., a “scan pass”) can be at least 1 pass, at least 2 passes, at least 3 passes, or even at least 4 passes. For example, the nozzle 100 can make from 1 pass to 10 passes, from 1 pass to 8 passes, from 1 pass to 6 passes, from 2 passes to 10 passes, from 2 passes to 8 passes, from 2 passes to 6 passes, from 3 passes to 10 passes, from 3 passes to 8 passes, from 3 passes to 6 passes, from 4 passes to 10 passes, from 4 passes to 8 passes, or from 4 passes to 6 passes.

The plasma plume 140 may be generated at various powers. In embodiments, the plasma plume 140 may be generated at a power of at least about 300 watts, such as a power of at least about 500 watts. For example, the plasma plume 140 can be generated at a power of from about 300 watts to about 800 watts, from about 300 watts to about 700 watts, from about 400 watts to about 800 watts, from about 400 watts to about 700 watts, from about 500 watts to about 800 watts, or from about 500 watts to about 700 watts.

It will be apparent to those skilled in the art that various modifications and variations can be made to the embodiments described herein without departing from the spirit and scope of the claimed subject matter. Thus it is intended that the specification cover the modifications and variations of the various embodiments described herein provided such modification and variations come within the scope of the appended claims and their equivalents.

1. A nozzle for an atmospheric pressure plasma jet (APPJ), the nozzle comprising:
a housing having an upstream end, a downstream end, and an inner wall defining a channel extending axially through the housing from the upstream end and the downstream end; and
a cathode disposed within the channel proximate to the upstream end of the housing, wherein the cathode and the housing are coaxial and form an annular flow path;
wherein:
the inner wall has a circular cross-sectional shape downstream of the cathode;
the downstream end of the housing comprises a first end surface;
the first end surface bisects at least a portion of the channel to form an opening through the first end surface; and
a first point on the first end surface at the inner wall is disposed downstream of a second point on the first end surface so that a plasma generated by the nozzle preferentially flows off axis in a direction of the second point.

2. The nozzle of claim 1, wherein the first end surface forms an angle less than or equal to 50 degrees with a plane perpendicular to a center axis of the nozzle.

3. The nozzle of claim 2, wherein the angle between the first end surface and the plane perpendicular to the center axis of the nozzle is from 1 degrees to 50 degrees, or from 10 degrees to 50 degrees, or from 10 degrees to 40 degrees, or from 15 degrees to 30 degrees.

4. The nozzle of either of claim 2, further comprising a second end surface, wherein the second end surface bisects another portion of the channel and is perpendicular to the center axis.

5. The nozzle of claim 1, wherein the first end surface bisects the entire channel, and a shape of the opening in the first end surface in a plane of the first end surface is elliptical.

6. The nozzle of claim 1, wherein the housing is an anode for formation of the APPJ.

7. The nozzle of claim 1, wherein a primary flow vector of the plasma exiting the channel through the opening is drawn toward the second point of the opening.

8. The nozzle of claim 1, wherein the upstream end of the housing is rotatably coupled to an anode of the APPJ.

9. The nozzle of claim 1, wherein the plasma is diffused as it exits the opening of the nozzle.

10. The nozzle of claim 1, wherein at least a portion of the opening is formed through cutting a portion of the nozzle.

11. The nozzle of claim 1, wherein the nozzle is cast out of a metal.

12. A method of material processing, the method comprising:
generating a plasma plume with an APPJ having the nozzle of claim 1, wherein the plasma plume has an average flow vector that diverges from a center axis of the nozzle;
rotating the nozzle, wherein the rotating causes the plasma plume to follow a circular path circumscribing the center axis of the nozzle; and
contacting the material with the plasma plume, wherein the average flow vector of the plasma plume diverging from the center axis of the nozzle and rotation of the nozzle provide consistent contact of the plasma plume with the material.

13. The method of claim 12, further comprising linearly translating the APPJ relative to the material.

14. The method of claim 12, further comprising linearly translating the material relative to the APPJ.

15. The method of claim 12, wherein a maximum temperature of the plasma plume is from 900° C. to 1,500° C.

16. The method of claim 12, wherein a maximum temperature difference within the plasma plume is less than or equal to 150° C.

17. The method of claim 12, wherein the material is a glass edge.

18. The method of claim 17, wherein the glass edge is cured to a roughness of less than 150 nanometers.

19. The method of claim 17, wherein the circular path circumscribing the center axis of the nozzle comprises an outer diameter of from 0.5 times to 2.5 times a glass edge width.

20. The method of claim 12, wherein a distance from the opening of the nozzle and the material is from 1.0 millimeters to 8.0 millimeters.

21. The method of claim 12 wherein the nozzle is rotated from 1,000 rotations per minute to 4,000 rotations per minute.

22. The method of claim 12, wherein a plasma flow out of the opening is laminar flow.
